(19) United States
(12) Patent Application Publication
(10) Pub. No.: US 2007/0007655 A1
(43) Pub. Date: Jan. 11, 2007

(54) Semiconductor device

(76) Inventor: Yuichi Miyamori, Kanagawa (JP)

Correspondence Address: ROBERT J. DEPKE;LEWIS T. STEADMAN, ROCKEY, DEPKE, LYONS AND KITZINGER, LLC, SUITE 5450 SEARS TOWER, CHICAGO, IL, 60606-6306, US

(21) Appl. No.: 11/476,238

(22) Filed: Jun. 27, 2006

(30) Foreign Application Priority Data
Jul. 6, 2005 (JP) JP2005-197043

(51) Int. Cl. H01L 23/52

(52) U.S. Cl. 257/758

(57) ABSTRACT

A semiconductor device that includes a pad over a multilevel interconnect formed by stacking an interconnect layer and an interlayer insulating film, the semiconductor device including a protective member that is formed in a continuous manner under outer circumference of the pad and has moisture resistance, the protective member surrounding the interlayer insulating film under the pad.

### CROSS REFERENCES TO RELATED APPLICATIONS

The present invention contains subject matter related to Japanese Patent Application JP 2005-197043 filed with the Japanese Patent Office on Jul. 6, 2005, the entire contents of which being incorporated herein by reference.

### BACKGROUND OF THE INVENTION

1. Field of the Invention

The present invention relates to a semiconductor device that suffers from no adverse effect of a crack generated in a pad and involves no increase in the element area.

2. Description of the Related Art

Miniaturization of semiconductor devices is being advanced in order to achieve a higher operation speed and a higher degree of integration. In step with the progress of the miniaturization, development of multilevel interconnects for coupling elements is being promoted. As the degree of miniaturization and integration of interconnects is enhanced, the influence of voltage drop and RC delay of the interconnects becomes nonnegligible. Therefore, as a countermeasure against this, reduction of the resistance of an interconnect material and the capacitance between interconnects is desired.

Accordingly, a structure becomes popular in which copper is used as an interconnect material and a low dielectric constant film (Low-k film) is used as interlayer films between interconnects, instead of used aluminum and a silicon dioxide (SiO₂) film, respectively in related art. A multilevel interconnect structure that employs the combination of copper and a Low-k film is formed mainly by a so-called damascene method. In this method, trenches (and contact holes) are formed in an interlayer film. Subsequently, a diffusion barrier layer against copper is formed in the trenches and copper is deposited on the diffusion barrier layer, followed by removal of excess copper over the interlayer film through chemical mechanical polishing (CMP).

Adequate repetition of this interconnect forming step leads to the formation of a multilevel interconnect structure. However, if the Low-k film absorbs moisture, the dielectric constant thereof and the amount of leakage current between interconnects increase. Therefore, the Low-k film is provided with a countermeasure against moisture. One example of methods for providing the Low-k film with a countermeasure against moisture is a guard ring that is provided to prevent moisture from being absorbed from the side faces of individual diced chips obtained from a wafer by dicing.

Semiconductor devices are diced into individual chips and then are subjected to packaging so as to be shipped as products. Preparatory for the dicing, operation tests, characteristic tests, and measurement and evaluation for selection are carried out for wafers. As a method for electrically coupling the semiconductor devices to measurement devices in these tests, a method in which a probe needle is brought into contact with a pad provided for an interconnect layer is generally used. To ensure the contact, an adequate load is applied to the probe needle, and this load application often causes a crack (pad crack) in an interlayer film under the pad. The occurrence of the pad crack results in a problem that water is allowed to intrude into the chip via the pad track as the intrusion path. As a countermeasure against this problem, a method in which a guard ring is also formed for the pad is disclosed in e.g. Japanese Patent Laid-open No. 2004-297022.

### SUMMARY OF THE INVENTION

However, this structure in which a guard ring is provided at the outer periphery of a pad involves a problem that the provision of the guard ring leads to an increase of the element area. In addition, cracks are not completely isolated from circuit-part interlayer films, and therefore complete prevention of moisture absorption is not achieved. If such a moisture absorption path exists, moisture absorption occurs when a crack is generated in a pad. This results in problems of an increase in the dielectric constant of interlayer films and an increase of the amount of leakage current between interconnects.

There is a need for the present invention to prevent the occurrence of cracks in circuit-part interlayer films even if a crack is generated in a pad, without causing an increase of the element area, to thereby solve the problems of an increase in the dielectric constant of interlayer films and an increase of the amount of leakage current between interconnects.

According to embodiments of the present invention, there are provided semiconductor devices that include a pad over a multilevel interconnect formed by stacking an interconnect layer and an interlayer insulating film. The semiconductor device of a first embodiment of the invention includes a protective member that is formed in a continuous manner under the outer circumference of the pad and has moisture resistance. The protective member surrounds the interlayer insulating film under the pad. The semiconductor device of a second embodiment of the invention includes a protective layer that is connected to the lower face of the pad and has moisture resistance.

In the semiconductor devices, the protective member or protective layer with moisture resistance is provided so that, even when a crack is generated in an interlayer film under the pad and the interlayer film absorbs moisture, the influence of the moisture absorption remains inside the interlayer film under the pad and the moisture does not penetrate into the external of the interlayer film under the pad. Due to the provision of the protective member or protective layer with moisture resistance, even when the pad suffers from a crack due to contact of a probe needle thereto or the like, water and so on that have entered an interlayer insulating film formed under the pad are blocked by the protective member or protective layer with moisture resistance.

In the semiconductor devices according to the first and second embodiments, the interlayer insulating film under the pad is surrounded by the protective member that is formed in a continuous manner under the outer circumference of the pad and has moisture resistance. Therefore, even when a crack is generated in the pad due to contact of a probe needle thereto, water and so on that have entered the interlayer insulating films formed under the pad are blocked by the protective member or protective layer having moisture resistance. Consequently, the water is precluded from penetrating into the external of the region surrounded by the protective member or into the external of the protective layer, which makes it possible to maintain the performance characteristics of the circuit-part interlayer insulating films formed outside the interlayer insulating films under the pad. Thus, an advantage is achieved that characteristic deterioration and reliability deterioration, such as increases of the capacitance between interconnects and the amount of leakage current between interconnects in the circuit part, can be suppressed without involving an area increase.

In addition, in the semiconductor device that includes the protective layer that is connected to the lower face of the pad and has moisture resistance, even when a crack is generated in the pad due to contact of a probe needle thereto, the development of the crack is blocked by the protective layer, which makes it possible to maintain the performance characteristics of the circuit-part interlayer insulating films formed outside the interlayer insulating films under the pad. Thus, an advantage is achieved that characteristic deterioration and reliability deterioration, such as increases of the capacitance between interconnects and the amount of leakage current between interconnects in the circuit part, can be suppressed without involving an area increase.

### BRIEF DESCRIPTION OF THE DRAWINGS

FIG. 1 is a schematic sectional view of the structure of a semiconductor device according to a first embodiment of the present invention;

FIG. 2 is a plane layout diagram of the semiconductor device according to the first embodiment;

FIG. 3 is a schematic sectional view of the structure of a semiconductor device according to a second embodiment of the invention;

FIG. 4 is a plane layout diagram of the semiconductor device according to the second embodiment;

FIG. 5 is a schematic sectional view of the structure of a semiconductor device according to a third embodiment of the invention;

FIG. 6 is a plane layout diagram of the semiconductor device according to the third embodiment;

FIG. 7 is a schematic sectional view of the structure of a semiconductor device according to a fourth embodiment of the invention;

FIG. 8 is a plane layout diagram of the semiconductor device according to the fourth embodiment;

FIG. 9 is a schematic sectional view of the structure of a semiconductor device according to a fifth embodiment of the invention;

FIG. 10 is a plane layout diagram of the semiconductor device according to the fifth embodiment;

FIG. 11 is a schematic sectional view of the structure of a semiconductor device according to a sixth embodiment of the invention;

FIG. 12 is a plane layout diagram of the semiconductor device according to the sixth embodiment;

FIGS. 13A to 13G are sectional views illustrating manufacturing steps for the semiconductor device of the first embodiment; and

FIGS. 14A to 14F are sectional views illustrating manufacturing steps for the semiconductor device,of the third embodiment.

### DETAILED DESCRIPTION OF THE PREFERRED EMBODIMENTS

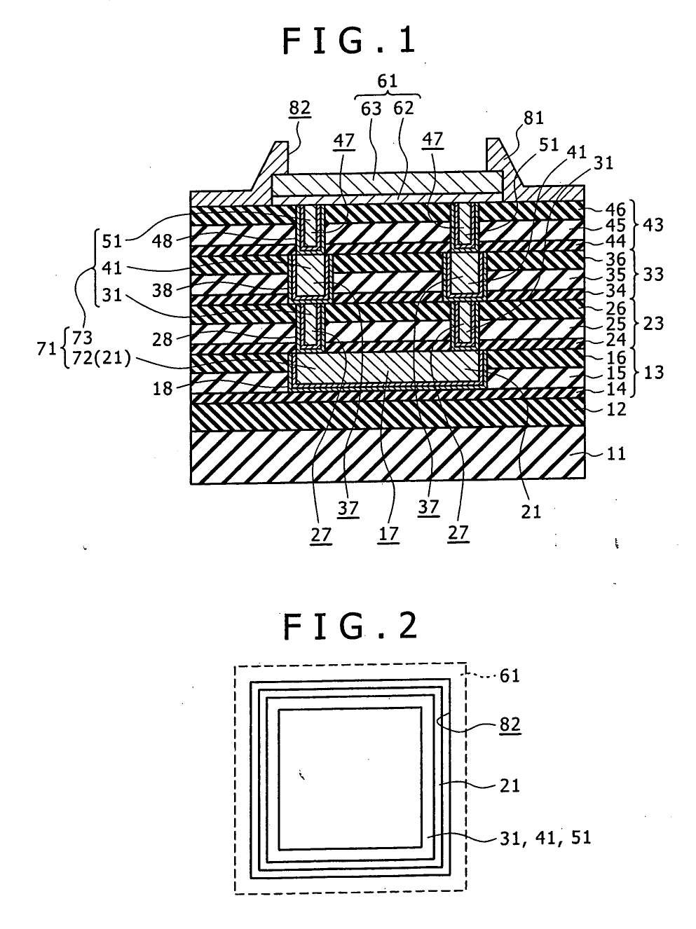

A semiconductor device according to a first embodiment of the invention will be described below with reference to the schematic structural sectional view of FIG. 1 and the plane layout diagram of FIG. 2.

Referring to FIG. 1, an insulating film 12 is formed on a semiconductor substrate 11. A silicon substrate is used as the semiconductor substrate 11 for example, and semiconductor elements such as transistors and capacitors, lower interconnects, etc. are formed thereon although not illustrated in the drawings. The insulating film 12 is formed by depositing a silicon dioxide (SiO₂) film to a thickness of 500 nm, for example.

Formed over the insulating film 12 is a first-interconnect interlayer insulating film 13 in which a first interconnect layer 21 is formed. Formed over the first-interconnect interlayer insulating film 13 is a first-contact interlayer insulating film 23 in which a first contact layer 31 connected to the first interconnect layer 21 is formed. Formed over the first-contact interlayer insulating film 23 is a second-interconnect interlayer insulating film 33 in which a second interconnect layer 41 connected to the first contact layer 31 is formed. Formed over the second-interconnect interlayer insulating film 33 is a second-contact interlayer insulating film 43 in which a second contact layer 51 connected to the second interconnect layer 41 is formed.

A pad 61 is formed on the second-contact interlayer insulating film 43. Furthermore, there is formed a protective member 71 that surrounds the respective interlayer insulating films under the pad 61 (the second-contact interlayer insulating film 43, the second-interconnect interlayer insulating film 33, and the first-contact interlayer insulating film 23) so as to seal these films. The protective member 71 includes a bottom portion 72 and a wall portion 73. The bottom portion 72 is formed of the first interconnect layer 21. The wall portion 73 serves to couple the bottom portion 72 with the pad 61 and surround the respective interlayer insulating films under the pad 61, and is formed of the first contact layer 31, the second interconnect layer 41, and the second contact layer 51. In this manner, the protective member 71 has a multilayer structure. Furthermore, the protective member 71 is composed of a material that has so high moisture resistance that water does not permeate the protective member 71. More specifically, it is formed of a metal material or a metal compound material that is used for the above-described interconnect layers and contact layers.

It is preferable for the wall portion 73 to be formed in such a manner that the wall portion 73 borders the outer circumference of the pad 61 when viewed in the plane layout (see FIG. 2).

One example of details of the respective members will be described below.

The first-interconnect interlayer insulating film 13 is formed by sequentially deposing a silicon nitride (SiN) film 14 with a thickness of 50 nm, a Low-k film 15 (silicon oxycarbide (SiOC) film) of 150 nm, and a silicon dioxide (SiO₂) film 16 of 150 nm.

A first interconnect trench 17 is formed in the first-interconnect interlayer insulating film 13. In the first interconnect trench 17, a barrier metal film 18 is formed, and the first interconnect layer 21 is formed thereon by burying copper (Cu) in the trench. The barrier metal film 18 is formed by depositing a tantalum (Ta) film to a thickness of 30 nm.

The first-contact interlayer insulating film 23 is formed by sequentially depositing a silicon nitride (SiN) film 24, a Low-k film 25 (silicon oxycarbide (SiOC) film), and a silicon dioxide (SiO₂) film 26. In the first-contact interlayer insulating film 23, a first contact hole 27 that is connected to the first interconnect layer 21 is formed. Inside the first contact hole 27, the first contact layer 31 is formed by filling the hole 27 with copper (Cu) with the intermediary of a barrier metal film 28 therebetween.

The second-interconnect interlayer insulating film 33 is formed by sequentially deposing a silicon nitride (SiN) film 34 with a thickness of 50 nm, a Low-k film 35 (silicon oxycarbide (SiOC) film) of 150 nm, and a silicon dioxide (SiO₂) film 36 of 150 nm.

A second interconnect trench 37 is formed in the second-interconnect interlayer insulating film 33. In the second interconnect trench 37, a barrier metal film 38 is formed, and the second interconnect layer 41 is formed thereon by burying copper (Cu) in the trench. The barrier metal film 38 is formed by depositing a tantalum (Ta) film to a thickness of 30 nm.

The second-contact interlayer insulating film 43 is formed by sequentially depositing a silicon nitride (SiN) film 44, a Low-k film 45 (silicon oxycarbide (SiOC) film), and a silicon dioxide (SiO₂) film 46. In the second-contact interlayer insulating film 43, a second contact hole 47 that is connected to the second interconnect layer 41 is formed. Inside the second contact hole 47, the second contact layer 51 is formed by filling the hole 47 with copper (Cu) with the intermediary of a barrier metal film 48 therebetween.

The pad 61 is formed by depositing a titanium (Ti) film 62 to a thickness of 50 nm, and then depositing thereon an aluminum (Al) film 63 to a thickness of 500 nm.

Over the second-contact interlayer insulating film 43, a passivation film 81 covering the pad 61 is formed. A pad opening 82 is formed in the passivation film 81 over the pad 61. The passivation film 81 is formed by depositing a silicon nitride (SiN) film to a thickness of 500 nm.

In the semiconductor device 1, the protective member 71 and the pad 61 seal the respective interlayer insulating films under the pad 61 (the second-contact interlayer insulating film 43, the second-interconnect interlayer insulating film 33, and the first-contact interlayer insulating film 23). Therefore, even when a crack is generated in the pad 61 due to contact of a probe needle thereto or the like, water and so on that have entered the interlayer insulating films formed under the pad 61 are blocked by the protective member 71 having moisture resistance, which precludes the water from penetrating into the external of the region surrounded by the protective member 71. Consequently, it is possible to maintain the performance characteristics of the circuit-part interlayer insulating films formed outside the pad 61 and the protective member 71 (the second-contact interlayer insulating film 43, the second-interconnect interlayer insulating film 33, the first-contact interlayer insulating film 23, and the first-interconnect interlayer insulating film 13). Thus, an advantage is achieved that characteristic deterioration and reliability deterioration, such as increases of the capacitance between interconnects and the amount of leakage current between interconnects in the circuit part, can be suppressed without involving an area increase.

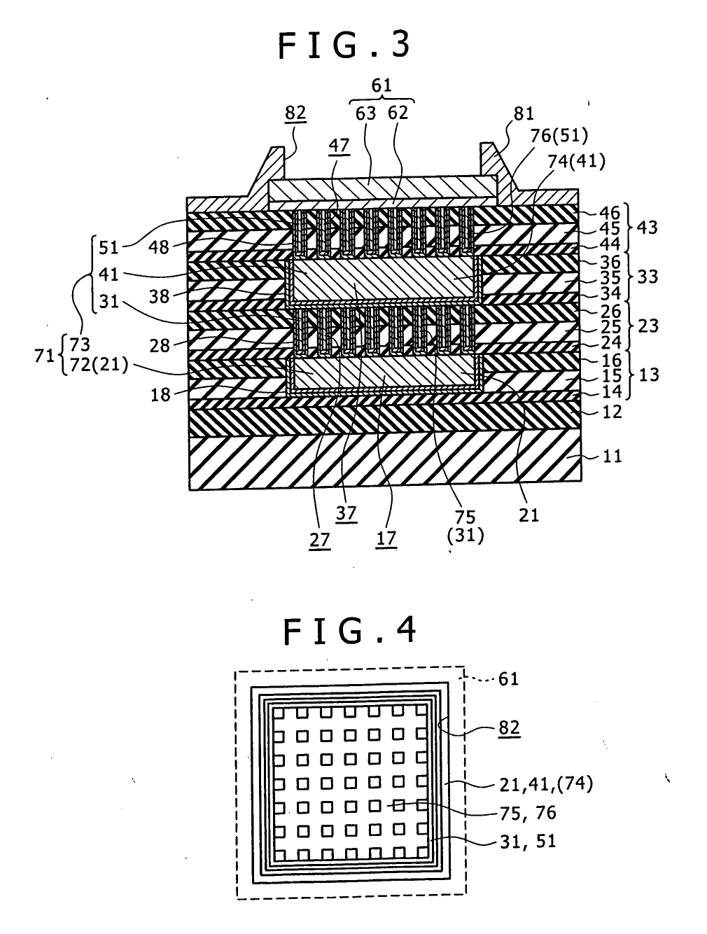

A semiconductor device according to a second embodiment of the invention will be described below with reference to the schematic structural sectional view of FIG. 3 and the plane layout diagram of FIG. 4.

Referring to FIG. 3, an insulating film 12 is formed on a semiconductor substrate 11. A silicon substrate is used as the semiconductor substrate 11 for example, and semiconductor elements such as transistors and capacitors, lower interconnects, etc. are formed thereon although not illustrated in the drawings. The insulating film 12 is formed by depositing a silicon dioxide (SiO₂) film to a thickness of 500 nm, for example.

Formed over the insulating film 12 is a first-interconnect interlayer insulating film 13 in which a first interconnect layer 21 is formed. Formed over the first-interconnect interlayer insulating film 13 is a first-contact interlayer insulating film 23 in which a first contact layer 31 connected to the first interconnect layer 21 is formed. Formed over the first-contact interlayer insulating film 23 is a second-interconnect interlayer insulating film 33 in which a second interconnect layer 41 connected to the first contact layer 31 is formed. Formed over the second-interconnect interlayer insulating film 33 is a second-contact interlayer insulating film 43 in which a second contact layer 51 connected to the second interconnect layer 41 is formed.

A pad 61 is formed on the second-contact interlayer insulating film 43. Furthermore, there is formed a protective member 71 that surrounds the respective interlayer insulating films under the pad 61 (the second-contact interlayer insulating film 43, the second-interconnect interlayer insulating film 33, and the first-contact interlayer insulating film 23). The protective member 71 includes a bottom portion 72 and a wall portion 73. The bottom portion 72 is formed of the first interconnect layer 21. The wall portion 73 serves to couple the bottom portion 72 with the pad 61 and surround the respective interlayer insulating films under the pad 61, and is formed of the first contact layer 31, the second interconnect layer 41, and the second contact layer 51. In this manner, the protective member 71 has a multilayer structure. Furthermore, the protective member 71 is composed of a material that has so high moisture resistance that water does not permeate the protective member 71. More specifically, it is formed of a metal material or a metal compound material that is used for the above-described interconnect layers and contact layers.

Inside the wall portion 73, an intermediate protective layer 74 formed of e.g. the second interconnect layer 41 is formed. The side circumference of the intermediate protective layer 74 is continuously connected to the wall portion 73. In other words, the side circumference of the intermediate protective layer 74 forms the wall portion 73. Furthermore, a partition wall 75 is formed between the bottom portion 72 and the intermediate protective layer 74, and a partition wall 76 is formed between the intermediate protective layer 74 and the pad 61. The partition walls 75 and 76 have a lattice shape when viewed in the plane layout. The partition wall 75 is formed of the first contact layer 31, and the partition wall 76 is formed of the second contact layer 51. The line width and line distance of the both walls are e.g. 0.5 μm and 0.5 μm, respectively. Similarly to the protective member 71, the intermediate protective layer 74 and the partition walls 75 and 76 are composed of a material that has so high moisture resistance that water does not permeate the layer 74, and the walls 75 and 76. For example, they are formed of a metal material or a metal compound material that is used for the above-described interconnect layers and contact layers. The partition walls 75 and 76 may be formed into, instead of a lattice shape, a honeycomb shape (each defined space is a hexagon), or a truss shape (each defined space is a triangle).

It is preferable for the wall portion 73 to be formed in such a manner that the wall portion 73 borders the outer circumference of the pad 61 when viewed in the plane layout (see FIG. 4).

One example of details of the respective members will be described below.

The first-interconnect interlayer insulating film 13 is formed by sequentially deposing a silicon nitride (SiN) film 14 with a thickness of 50 nm, a Low-k film 15 (silicon oxycarbide (SiOC) film) of 150 nm, and a silicon dioxide (SiO₂) film 16 of 150 nm.

A first interconnect trench 17 is formed in the first-interconnect interlayer insulating film 13. In the first interconnect trench 17, a barrier metal film 18 is formed, and the first interconnect layer 21 is formed thereon by burying copper (Cu) in the trench. The barrier metal film 18 is formed by depositing a tantalum (Ta) film to a thickness of 30 nm.

The first-contact interlayer insulating film 23 is formed by sequentially depositing a silicon nitride (SiN) film 24, a Low-k film 25 (silicon oxycarbide (SiOC) film), and a silicon dioxide (SiO₂) film 26. In the first-contact interlayer insulating film 23, a first contact hole 27 that is connected to the first interconnect layer 21 is formed. Inside the first contact hole 27, the first contact layer 31 is formed by filling the hole 27 with copper (Cu) with the intermediary of a barrier metal film 28 therebetween.

The second-interconnect interlayer insulating film 33 is formed by sequentially deposing a silicon nitride (SiN) film 34 with a thickness of 50 nm, a Low-k film 35 (silicon oxycarbide (SiOC) film) of 150 nm, and a silicon dioxide (SiO₂) film 36 of 150 nm.

A second interconnect trench 37 is formed in the second-interconnect interlayer insulating film 33. In the second interconnect trench 37, a barrier metal film 38 is formed, and the second interconnect layer 41 is formed thereon by burying copper (Cu) in the trench. The barrier metal film 38 is formed by depositing a tantalum (Ta) film to a thickness of 30 nm.

The second-contact interlayer insulating film 43 is formed by sequentially depositing a silicon nitride (SiN) film 44, a Low-k film 45 (silicon oxycarbide (SiOC) film), and a silicon dioxide (SiO₂) film 46. In the second-contact interlayer insulating film 43, a second contact hole 47 that is connected to the second interconnect layer 41 is formed. Inside the second contact hole 47, the second contact layer 51 is formed by filling the hole 47 with copper (Cu) with the intermediary of a barrier metal film 48 therebetween.

The pad 61 is formed by depositing a titanium (Ti) film 62 to a thickness of 50 nm, and then depositing thereon an aluminum (Al) film 63 to a thickness of 500 nm.

Over the second-contact interlayer insulating film 43, a passivation film 81 covering the pad 61 is formed. A pad opening 82 is formed in the passivation film 81 over the pad 61. The passivation film 81 is formed by depositing a silicon nitride (SiN) film to a thickness of 500 nm.

In the semiconductor device 1, the protective member 71 and the pad 61 seal the respective interlayer insulating films under the pad 61 (the second-contact interlayer insulating film 43, the second-interconnect interlayer insulating film 33, and the first-contact interlayer insulating film 23). Therefore, even when a crack is generated in the pad 61 due to contact of a probe needle thereto or the like, water and so on that have entered the interlayer insulating films formed under the pad 61 are blocked by the protective member 71 having moisture resistance, which precludes the water from penetrating into the external of the region surrounded by the protective member 71. Consequently, it is possible to maintain the performance characteristics of the circuit-part interlayer insulating films formed outside the pad 61 and the protective member 71 (the second-contact interlayer insulating film 43, the second-interconnect interlayer insulating film 33, the first-contact interlayer insulating film 23, and the first-interconnect interlayer insulating film 13). Thus, an advantage is achieved that characteristic deterioration and reliability deterioration, such as increases of the capacitance between interconnects and the amount of leakage current between interconnects in the circuit part, can be suppressed without involving an area increase.

Furthermore, since the intermediate protective layer 74 and the partition walls 75 and 76 are provided, diffusion of water can be suppressed to the minimum even when the pad 61 is damaged due to contact of a probe needle thereto. Specifically, since interlayer insulating films are separated by the protective member 71, the intermediate protective layer 74 and the partition walls 75 and 76, water permeates the interlayer insulating films under the damaged pad 61, while the water does not permeate interlayer insulating films that are adjacent to the interlayer insulating films under the damaged pad 61 with the intermediary of the intermediate protective layer 74 and the partition walls 75 and 76 therebetween. In particular, in each of the partition walls 75 and 76, a large number of wall plates are arranged in the same contact layer, which offers higher moisture resistance.

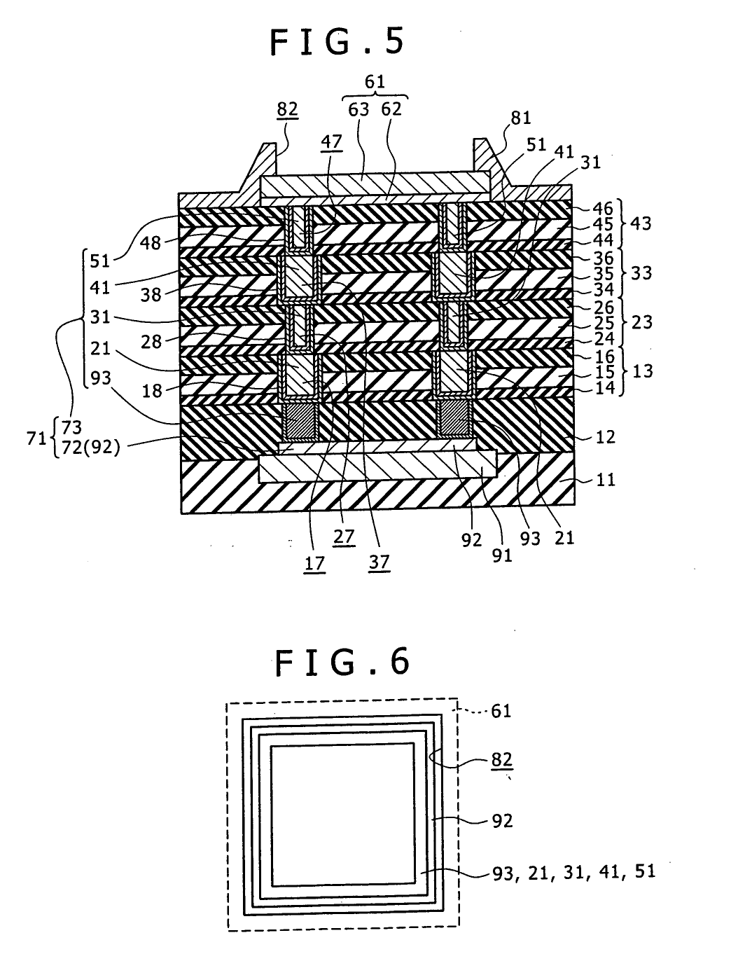

A semiconductor device according to a third embodiment of the invention will be described below with reference to the schematic structural sectional view of FIG. 5 and the plane layout diagram of FIG. 6.

Referring to FIG. 5, an element isolation region 91 is formed in a semiconductor substrate 11. The semiconductor substrate 11 is formed of e.g. a silicon substrate. On the semiconductor substrate 11, semiconductor elements such as transistors and capacitors, a gate electrode layer, etc. are formed although not illustrated in the drawings. For example, a part of a gate electrode layer 92 is formed also on the element isolation region 91. There is provided an insulating film 12 in which a lower contact layer 93 connected to the gate electrode layer 92 is formed. The insulating film 12 is formed by depositing a silicon dioxide (SiO₂) film to a thickness of 500 nm, for example.

Formed over the insulating film 12 is a first-interconnect interlayer insulating film 13 in which a first interconnect layer 21 is formed. Formed over the first-interconnect interlayer insulating film 13 is a first-contact interlayer insulating film 23 in which a first contact layer 31 connected to the first interconnect layer 21 is formed. Formed over the first-contact interlayer insulating film 23 is a second-interconnect interlayer insulating film 33 in which a second interconnect layer 41 connected to the first contact layer 31 is formed. Formed over the second-interconnect interlayer insulating film 33 is a second-contact interlayer insulating film 43 in which a second contact layer 51 connected to the second interconnect layer 41 is formed.

A pad 61 is formed on the second-contact interlayer insulating film 43. Furthermore, there is formed a protective member 71 that surrounds the respective interlayer insulating films under the pad 61 (the second-contact interlayer insulating film 43, the second-interconnect interlayer insulating film 33, the first-contact interlayer insulating film 23, the first-interconnect interlayer insulating film 13, and the insulating film 12). The protective member 71 includes a bottom port-ion 72 and a wall portion 73. The bottom portion 72 is formed of the gate electrode layer 92 on the element isolation region 91. The wall portion 73 serves to couple the bottom portion 72 with the pad 61 and surround the respective interlayer insulating films under the pad 61 to thereby seal the films. The wall portion 73 is formed of the lower contact layer 93, the first interconnect layer 21, the first contact layer 31, the second interconnect layer 41, and the second contact layer 51. In this manner, the protective member 71 has a multilayer structure. Furthermore, the protective member 71 is composed of a material that has so high moisture resistance that water does not permeate the protective member 71. More specifically, it is formed of a metal material or a metal compound material that is used for the above-described interconnect layers and contact layers.

It is preferable for the wall portion 73 to be formed in such a manner that the wall portion 73 borders the outer circumference of the pad 61 when viewed in the plane layout (see FIG. 6).

One example of details of the respective members will be described below.

The first-interconnect interlayer insulating film 13 is formed by sequentially deposing a silicon nitride (SiN) film 14 with a thickness of 50 nm, a Low-k film 15 (silicon oxycarbide (SiOC) film) of 150 nm, and a silicon dioxide (SiO₂) film 16 of 150 nm.

A first interconnect trench 17 is formed in the first-interconnect interlayer insulating film 13. In the first interconnect trench 17, a barrier metal film 18 is formed, and the first interconnect layer 21 is formed thereon by burying copper (Cu) in the trench. The barrier metal film 18 is formed by depositing a tantalum (Ta) film to a thickness of 30 nm.

The first-contact interlayer insulating film 23 is formed by sequentially depositing a silicon nitride (SiN) film 24, a Low-k film 25 (silicon oxycarbide (SiOC) film), and a silicon dioxide (SiO₂) film 26. In the first-contact interlayer insulating film 23, a first contact hole 27 that is connected to the first interconnect layer 21 is formed. Inside the first contact hole 27, the first contact layer 31 is formed by filling the hole 27 with copper (Cu) with the intermediary of a barrier metal film 28 therebetween.

The second-interconnect interlayer insulating film 33 is formed by sequentially deposing a silicon nitride (SiN) film 34 with a thickness of 50 nm, a Low-k film 35 (silicon oxycarbide (SiOC) film) of 150 nm, and a silicon dioxide (SiO₂) film 36 of 150 nm.

A second interconnect trench 37 is formed in the second-interconnect interlayer insulating-film 33. In the second interconnect trench 37, a barrier metal film 38 is formed, and the second interconnect layer 41 is formed thereon by burying copper (Cu) in the trench. The barrier metal film 38 is formed by depositing a tantalum (Ta) film to a thickness of 30 nm.

The second-contact interlayer insulating film 43 is formed by sequentially depositing a silicon nitride (SiN) film 44, a Low-k film 45 (silicon oxycarbide (SiOC) film), and a silicon dioxide (SiO₂) film 46. In the second-contact interlayer insulating film 43, a second contact hole 47 that is connected to the second interconnect layer 41 is formed. Inside the second contact hole 47, the second contact layer 51 is formed by filling the hole 47 with copper (Cu) with the intermediary of a barrier metal film 48 therebetween.

The pad 61 is formed by depositing a titanium (Ti) film 62 to a thickness of 50 nm, and then depositing thereon an aluminum (Al) film 63 to a thickness of 500 nm.

Over the second-contact interlayer insulating film 43, a passivation film 81 covering the pad 61 is formed. A pad opening 82 is formed in the passivation film 81 over the pad 61. The passivation film 81 is formed by depositing a silicon nitride (SiN) film to a thickness of 500 nm.

In the semiconductor device 1, the protective member 71 and the pad 61 seal the respective interlayer insulating films under the pad 61 (the second-contact interlayer insulating film 43, the second-interconnect interlayer insulating film 33, the first-contact interlayer insulating film 23, the first-interconnect interlayer insulating film 13, and the insulating film 12). Therefore, even when a crack is generated in the pad 61 due to contact of a probe needle thereto or the like, water and so on that have entered the interlayer insulating films formed under the pad 61 are blocked by the protective member 71 having moisture resistance, which precludes the water from penetrating into the external of the region surrounded by the protective member 71. Consequently, it is possible to maintain the performance characteristics of the circuit-part interlayer insulating films formed outside the pad 61 and the protective member 71 (the second-contact interlayer insulating film 43, the second-interconnect interlayer insulating film 33, the first-contact interlayer insulating film 23, the first-interconnect interlayer insulating film 13, and the insulating film 12). Thus, an advantage is achieved that characteristic deterioration and reliability deterioration, such as increases of the capacitance between interconnects and the amount of leakage current between interconnects in the circuit part, can be suppressed without involving an area increase.

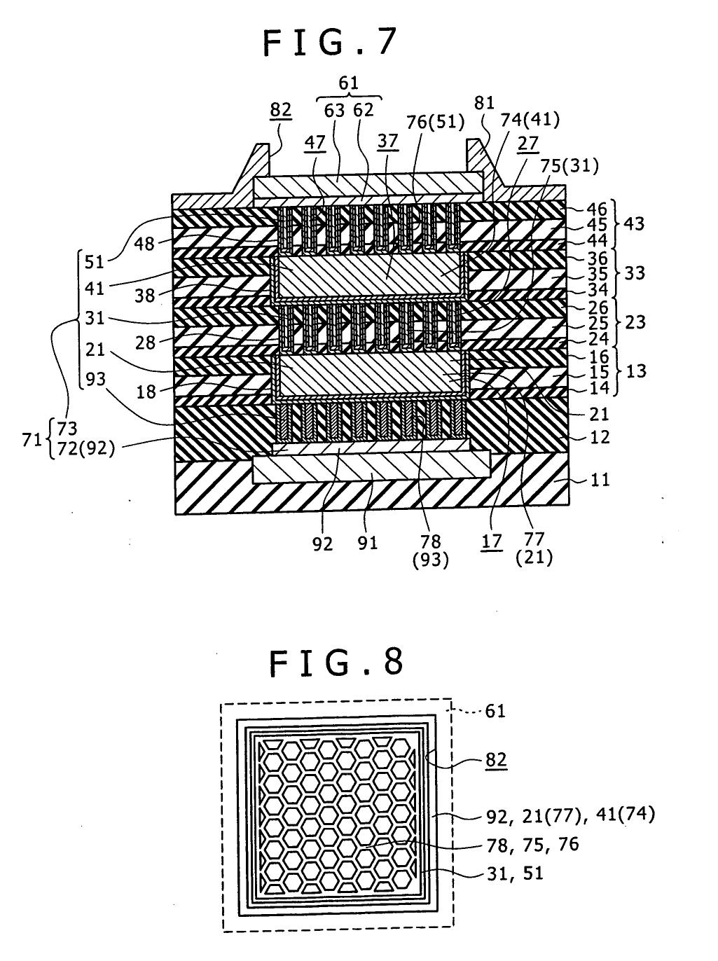

A semiconductor device according to a fourth embodiment of the invention will be described below with reference to the schematic structural sectional view of FIG. 7 and the plane layout diagram of FIG. 8.

Referring to FIG. 7, an element isolation region 91 is formed in a semiconductor substrate 11. The semiconductor substrate 11 is formed of e.g. a silicon substrate. On the semiconductor substrate 11, semiconductor elements such as transistors and capacitors, a gate electrode layer, etc. are formed although not illustrated in the drawings. For example, a part of a gate electrode layer 92 is formed also on the element isolation region 91. There is provided an insulating film 12 in which a lower contact layer 93 connected to the gate electrode layer 92 is formed. The insulating film 12 is formed by depositing a silicon dioxide (SiO₂) film to a thickness of 500 nm, for example.

Formed over the insulating film 12 is a first-interconnect interlayer insulating film 13 in which a first interconnect layer 21 is formed. Formed over the first-interconnect interlayer insulating film 13 is a first-contact interlayer insulating film 23 in which a first contact layer 31 connected to the first interconnect layer 21 is formed. Formed over the first-contact interlayer insulating film 23 is a second-interconnect interlayer insulating film 33 in which a second interconnect layer 41 connected to the first contact layer 31 is formed. Formed over the second-interconnect interlayer insulating film 33 is a second-contact interlayer insulating film 43 in which a second contact layer 51 connected to the second interconnect layer 41 is formed.

A pad 61 is formed on the second-contact interlayer insulating film 43. Furthermore, there is formed a protective member 71 that surrounds the respective interlayer insulating films under the pad 61 (the second-contact interlayer insulating film 43, the second-interconnect interlayer insulating film 33, the first-contact interlayer insulating film 23, the first-interconnect interlayer insulating film 13, and the insulating film 12). The protective member 71 includes a bottom portion 72 and a wall portion 73. The bottom portion 72 is formed of the gate electrode layer 92 on the element isolation region 91. The wall portion 73 serves to couple the bottom portion 72 with the pad 61 and surround the respective interlayer insulating films under the pad 61. The wall portion 73 is formed of the lower contact layer 93, the first interconnect layer 21, the first contact layer 31, the second interconnect layer 41, and the second contact layer 51. In this manner, the protective member 71 has a multilayer structure. Furthermore, the protective member 71 is composed of a material that has so high moisture resistance that water does not permeate the protective member 71. More specifically, it is formed of a metal material or a metal compound material that is used for the above-described interconnect layers and contact layers.

Inside the wall portion 73, intermediate protective layers 74 and 77 formed of the second interconnect layer 41 and the first interconnect layer 21, respectively, are formed. The side circumferences of the intermediate protective layers 74 and 77 are continuously connected to the wall portion 73. Furthermore, a partition wall 78 is formed between the bottom portion 72 and the intermediate protective layer 77, a partition wall 75 is formed between the intermediate protective layers 77 and 74, and a partition wall 76 is formed between the intermediate protective layer 74 and the pad 61. The partition walls 78, 75 and 76 have a honeycomb shape (each defined space is a hexagon) when viewed in the plane layout. In the partition walls 78, 75 and 76, the line width and the length of each side are both set to e.g. 0.5 μm. Similarly to the protective member 71, the intermediate protective layers 74 and 77, and the partition walls 78, 75 and 76 are composed of a material having so high moisture resistance that water does not permeate the layers 74 and 77 and the walls 78, 75 and 76. More specifically, they are formed of a metal material or a metal compound material that is used for the above-described interconnect layers and contact layers. The partition walls 78, 75 and 76 may be formed into, instead of a honeycomb shape, a lattice shape, or a truss shape (each defined space is a triangle).

It is preferable for the wall portion 73 to be formed in such a manner that the wall portion 73 borders the outer circumference of the pad 61 when viewed in the plane layout (see FIG. 8).

One example of details of the respective members will be described below.

The first-interconnect interlayer insulating film 13 is formed by sequentially deposing a silicon nitride (SiN) film 14 with a thickness of 50 nm, a Low-k film 15 (silicon oxycarbide (SiOC) film) of 150 nm, and a silicon dioxide (SiO₂) film 16 of 150 nm.

A first interconnect trench 17 is formed in the first-interconnect interlayer insulating film 13. In the first interconnect trench 17, a barrier metal film 18 is formed, and the first interconnect layer 21 is formed thereon by burying copper (Cu) in the trench. The barrier metal film 18 is formed by depositing a tantalum (Ta) film to a thickness of 30 nm.

The first-contact interlayer insulating film 23 is formed by sequentially depositing a silicon nitride (SiN) film 24, a Low-k film 25 (silicon oxycarbide (SiOC) film), and a silicon dioxide (SiO₂) film 26. In the first-contact interlayer insulating film 23, a first contact hole 27 that is connected to the first interconnect layer 21 is formed. Inside the first contact hole 27, the first contact layer 31 is formed by filling the hole 27 with copper (Cu) with the intermediary of a barrier metal film 28 therebetween.

The second-interconnect interlayer insulating film 33 is formed by sequentially deposing a silicon nitride (SiN) film 34 with a thickness of 50 nm, a Low-k film 35 (silicon oxycarbide (SiOC) film) of 150 nm, and a silicon dioxide (SiO₂) film 36 of 150 nm.

A second interconnect trench 37 is formed in the second-interconnect interlayer insulating film 33. In the second interconnect trench 37, a barrier metal film 38 is formed, and the second interconnect layer 41 is formed thereon by burying copper (Cu) in the trench. The barrier metal film 38 is formed by depositing a tantalum (Ta) film to a thickness of 30 nm.

The second-contact interlayer insulating film 43 is formed by sequentially depositing a silicon nitride (SiN) film 44, a Low-k film 45 (silicon oxycarbide (SiOC) film), and a silicon dioxide (SiO₂) film 46. In the second-contact interlayer insulating film 43, a second contact hole 47 that is connected to the second interconnect layer 41 is formed. Inside the second contact hole 47, the second contact layer 51 is formed by filling the hole 47 with copper (Cu) with the intermediary of a barrier metal film 48 therebetween.

The pad 61 is formed by depositing a titanium (Ti) film 62 to a thickness of 50 nm, and then depositing thereon an aluminum (Al) film 63 to a thickness of 500 nm.

Over the second-contact interlayer insulating film 43, a passivation film 81 covering the pad 61 is formed. A pad opening 82 is formed in the passivation film 81 over the pad 61. The passivation film 81 is formed by depositing a silicon nitride (SiN) film to a thickness of 500 nm.

In the semiconductor device 1, the protective member 71 and the pad 61 seal the respective interlayer insulating films under the pad 61 (the second-contact interlayer insulating film 43, the second-interconnect interlayer insulating film 33, the first-contact interlayer insulating film 23, the first-interconnect interlayer insulating film 13, and the insulating film 12). Therefore, even when a crack is generated in the pad 61 due to contact of a probe needle thereto or the like, water and so on that have entered the interlayer insulating films formed under the pad 61 are blocked by the protective member 71 having moisture resistance, which precludes the water from penetrating into the external of the region surrounded by the protective member 71. Consequently, it is possible to maintain the performance characteristics of the circuit-part interlayer insulating films formed outside the pad 61 and the protective member 71 (the second-contact interlayer insulating film 43, the second-interconnect interlayer insulating film 33, the first-contact interlayer insulating film 23, the first-interconnect interlayer insulating film 13, and the insulating film 12). Thus, an advantage is achieved that characteristic deterioration and reliability deterioration, such as increases of the capacitance between interconnects and the amount of leakage current between interconnects in the circuit part, can be suppressed without involving an area increase.

Furthermore, since the intermediate protective layers 74 and 77 and the partition walls 78, 75 and 76 are provided, diffusion of water can be suppressed to the minimum even when the pad 61 is damaged due to contact of a probe needle thereto. Specifically, since interlayer insulating films are separated by the protective member 71, the intermediate protective layers 74 and 77, and the partition walls 78, 75 and 76, water permeates the interlayer insulating films under the damaged pad 61, while the water does not permeate interlayer insulating films that are adjacent to the interlayer insulating films under the damaged pad 61 with the intermediary of the intermediate protective layers 74 and 77 and the partition walls 78, 75 and 76 therebetween. In particular, in each of the partition walls 78, 75 and 76, a large number of wall plates are arranged in the same contact layer, which offers higher moisture resistance. In addition, the plane layout of each of the partition walls 78, 75 and 76 is such that each wall plate does not extend in a straight line between positions under both ends of the pad 61. Therefore, a crack generated along the boundary between a contact layer and a contact interlayer insulating film does not extend in a straight line, which can enhance the resistance against such cracks.

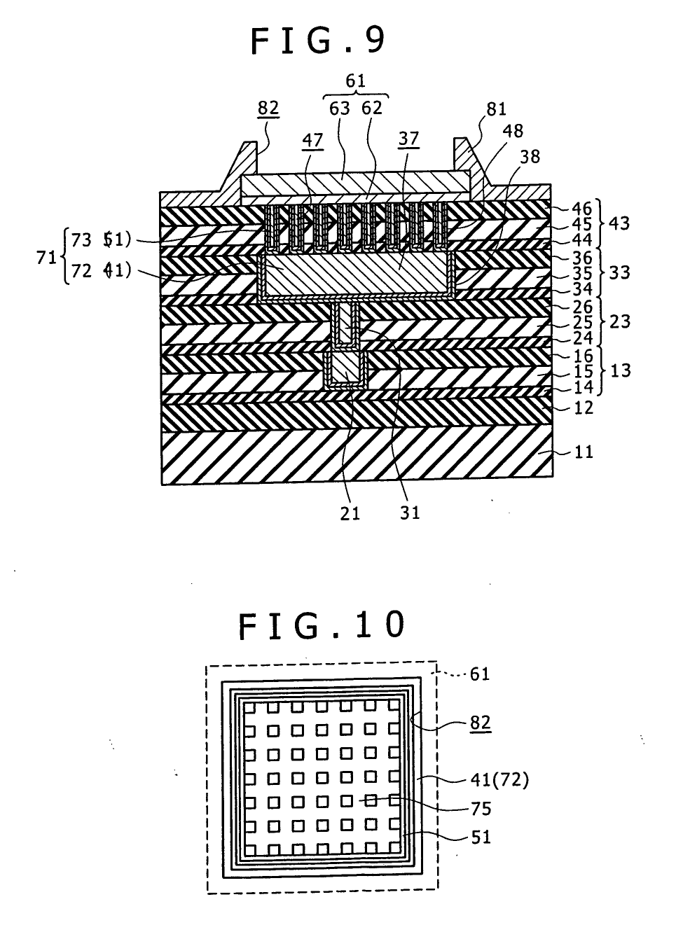

A semiconductor device according to a fifth embodiment of the invention will be described below with reference to the schematic structural sectional view of FIG. 9 and the plane layout diagram of FIG. 10.

Referring to FIG. 9, an insulating film 12 is formed on a semiconductor substrate 11. A silicon substrate is used as the semiconductor substrate 11 for example, and semiconductor elements such as transistors and capacitors, lower interconnects, etc. are formed thereon although not illustrated in the drawings. The insulating film 12 is formed by depositing a silicon dioxide (SiO₂) film to a thickness of 500 nm, for example.

Formed over the insulating film 12 is a first-interconnect interlayer insulating film 13 in which a first interconnect layer 21 is formed. Formed over the first-interconnect interlayer insulating film 13 is a first-contact interlayer insulating film 23 in which a first contact layer 31 connected to the first interconnect layer 21 is formed. Formed over the first-contact interlayer insulating film 23 is a second-interconnect interlayer insulating film 33 in which a second interconnect layer 41 connected to the first contact layer 31 is formed. Formed over the second-interconnect interlayer insulating film 33 is a second-contact interlayer insulating film 43 in which a second contact layer 51 connected to the second interconnect layer 41 is formed.

A pad 61 is formed on the second-contact interlayer insulating film 43. In addition, a protective member 71 is formed to surround the second-contact interlayer insulating film 43 under the pad 61. The protective member 71 includes a bottom portion 72 and a wall portion 73. The bottom portion 72 is formed of the second interconnect layer 41. The wall portion 73 serves to couple the bottom portion 72 with the pad 61 and surround the second-contact interlayer insulating film 43 under the pad 61, and is formed of the second contact layer 51. In this manner, the protective member 71 has a multilayer structure. Furthermore, the protective member 71 is composed of a material that has so high moisture resistance that water does not permeate the protective member 71. More specifically, it is formed of a metal material or a metal compound material that is used for the above-described interconnect layers and contact layers.

It is preferable for the wall portion 73 to be formed in such a manner that the wall portion 73 borders the outer circumference of the pad 61 when viewed in the plane layout (see FIG. 10).

A partition wall 75 that has a lattice shape when viewed in the plane layout is formed between the bottom portion 72 and the pad 61. The partition wall 75 has a line width of 0.5 μm and a line distance of 0.5 μm, for example. Similarly to the protective member 71, the partition wall 75 is composed of a material having so high moisture resistance that water does not permeate the partition wall 75. More specifically, it is formed of a metal material or a metal compound material that is used for the above-described interconnect layers and contact layers. The partition wall 75 may be formed into, instead of a lattice shape, a honeycomb shape (each defined space is a hexagon), or a truss shape (each defined space is a triangle).

The lower side of the bottom portion 72 is coupled to the first contact layer 31 and the first interconnect layer 21, which are the lower layers, so that the bottom portion 72 can be provided with the potential of e.g. the first interconnect layer 21. In this manner, a potential of a component that is at a lower level than the bottom portion 72 of the protective member 71 can be extracted. Alternatively, the protective member 71 may be coupled to another second interconnect layer 41 although not illustrated in the drawings, so that the protective member 71 is provided with the same potential as that of the coupled interconnect.

One example of details of the respective members will be described below.

The first-interconnect interlayer insulating film 13 is formed by sequentially deposing a silicon nitride (SiN) film 14 with a thickness of 50 nm, a Low-k film 15 (silicon oxycarbide (SiOC) film) of 150 nm, and a silicon dioxide (SiO₂) film 16 of 150 nm.

A first interconnect trench 17 is formed in the first-interconnect interlayer insulating film 13. In the first interconnect trench 17, a barrier metal film 18 is formed, and the first interconnect layer 21 is formed thereon by burying copper (Cu) in the trench. The barrier metal film 18 is formed by depositing a tantalum (Ta) film to a thickness of 30 nm.

The first-contact interlayer insulating film 23 is formed by sequentially depositing a silicon nitride (SiN) film 24, a Low-k film 25 (silicon oxycarbide (SiOC) film), and a silicon dioxide (SiO₂) film 26. In the first-contact interlayer insulating film 23, a first contact hole 27 that is connected to the first interconnect layer 21 is formed. Inside the first contact hole 27, the first contact layer 31 is formed by filling the hole 27 with copper (Cu) with the intermediary of a barrier metal film 28 therebetween.

The second-interconnect interlayer insulating film 33 is formed by sequentially deposing a silicon nitride (SiN) film 34 with a thickness of 50 nm, a Low-k film 35 (silicon oxycarbide (SiOC) film) of 150 nm, and a silicon dioxide (SiO₂) film 36 of 150 nm.

A second interconnect trench 37 is formed in the second-interconnect interlayer insulating film 33. In the second interconnect trench 37, a barrier metal film 38 is formed, and the second interconnect layer 41 is formed thereon by burying copper (Cu) in the trench. The barrier metal film 38 is formed by depositing a tantalum (Ta) film to a thickness of 30 nm.

The second-contact interlayer insulating film 43 is formed by sequentially depositing a silicon nitride (SiN) film 44, a Low-k film 45 (silicon oxycarbide (SiOC) film), and a silicon dioxide (SiO₂) film 46. In the second-contact interlayer insulating film 43, a second contact hole 47 that is connected to the second interconnect layer 41 is formed. Inside the second contact hole 47, the second contact layer 51 is formed by filling the hole 47 with copper (Cu) with the intermediary of a barrier metal film 48 therebetween.

The pad 61 is formed by depositing a titanium (Ti) film 62 to a thickness of 50 nm, and then depositing thereon an aluminum (Al) film 63 to a thickness of 500 nm.

Over the second-contact interlayer insulating film 43, a passivation film 81 covering the pad 61 is formed. A pad opening 82 is formed in the passivation film 81 over the pad 61. The passivation film 81 is formed by depositing a silicon nitride (SiN) film to a thickness of 500 nm.

In the semiconductor device 1, the protective member 71 and the pad 61 seal the second-contact interlayer insulating film 43 under the pad 61. Therefore, even when a crack is generated in the pad 61 due to contact of a probe needle thereto or the like, water and so on that have entered the second-contact interlayer insulating film 43 formed under the pad 61 are blocked by the protective member 71 having moisture resistance, which precludes the water from penetrating into the external of the region surrounded by the protective member 71. Consequently, it is possible to maintain the performance characteristics of the circuit-part interlayer insulating films formed outside the pad 61 and the protective member 71 (the second-contact interlayer insulating film 43, the second-interconnect interlayer insulating film 33, the first-contact interlayer insulating film 23, and the first-interconnect interlayer insulating film 13). Thus, an advantage is achieved that characteristic deterioration and reliability deterioration, such as increases of the capacitance between interconnects and the amount of leakage current between interconnects in the circuit part, can be suppressed without involving an area increase.

Furthermore, the first interconnect layer 21, which is below the protective member 71, can be used for the circuit part, and therefore size reduction of the circuit is allowed.

A semiconductor device according to a sixth embodiment of the invention will be described below with reference to the schematic structural sectional view of FIG. 11 and the plane layout diagram of FIG. 12.

Referring to FIG. 11, an insulating film 12 is formed on a semiconductor substrate 11. A silicon substrate is used as the semiconductor substrate 11 for example, and semiconductor elements such as transistors and capacitors, lower interconnects, etc. are formed thereon although not illustrated in the drawings. The insulating film 12 is formed by depositing a silicon dioxide (SiO₂) film to a thickness of 500 nm, for example.

Formed over the insulating film 12 is a first-interconnect interlayer insulating film 13 in which a first interconnect layer 21 is formed. Formed over the first-interconnect interlayer insulating film 13 is a first-contact interlayer insulating film 23 in which a first contact layer 31 connected to the first interconnect layer 21 is formed. Formed over the first-contact interlayer insulating film 23 is a second-interconnect interlayer insulating film 33 in which a second interconnect layer 41 connected to the first contact layer 31 is formed. Formed over the second-interconnect interlayer insulating film 33 is a second-contact interlayer insulating film 43 in which a second contact layer 51 connected to the second interconnect layer 41 is formed.

A pad 61 is formed on the second-contact interlayer insulating film 43. Furthermore, there is formed a protective member 71 for the second-contact interlayer insulating film 43, the second-interconnect interlayer insulating film 33, the first-contact interlayer insulating film 23, and the first-interconnect interlayer insulating film 13 under the pad 61. The protective member 71 is formed of stacked protective layers 101, 102, 103 and 104 that each have a shape similar to the shape of the pad 61 and are formed of the first interconnect layer 21, the first contact layer 31, the second interconnect layer 41 and the second contact layer 51, respectively. The protective layers 101, 102, 103 and 104 are composed of a material that has so high moisture resistance that water does not permeate these layers. More specifically, they are formed of a metal material or a metal compound material that is used for the above-described interconnect layers and contact layers.

It is preferable for the protective layers 101, 102, 103 and 104 to be formed in such a manner that these layers 101 to 104 border the outer circumference of the pad 61 when viewed in the plane layout (see FIG. 12).

One example of details of the respective members will be described below.

The first-interconnect interlayer insulating film 13 is formed by sequentially deposing a silicon nitride (SiN) film 14 with a thickness of 50 nm, a Low-k film 15 (silicon oxycarbide (SiOC) film) of 150 nm, and a silicon dioxide (SiO₂) film 16 of 150 nm.

A first interconnect trench 17 is formed in the first-interconnect interlayer insulating film 13. In the first interconnect trench 17, a barrier metal film 18 is formed, and the first interconnect layer 21 is formed thereon by burying copper (Cu) in the trench. The barrier metal film 18 is formed by depositing a tantalum (Ta) film to a thickness of 30 nm.

The first-contact interlayer insulating film 23 is formed by sequentially depositing a silicon nitride (SiN) film 24, a Low-k film 25 (silicon oxycarbide (SiOC) film), and a silicon dioxide (SiO₂) film 26. In the first-contact interlayer insulating film 23, a first contact hole 27 that is connected to the first interconnect layer 21 is formed. Inside the first contact hole 27, the first contact layer 31 is formed by filling the hole 27 with copper (Cu) with the intermediary of a barrier metal film 28 therebetween.

The second-interconnect interlayer insulating film 33 is formed by sequentially deposing a silicon nitride (SiN) film 34 with a thickness of 50 nm, a Low-k film 35 (silicon oxycarbide (SiOC) film) of 150 nm, and a silicon dioxide (SiO₂) film 36 of 150 nm.

A second interconnect trench 37 is formed in the second-interconnect interlayer insulating film 33. In the second interconnect trench 37, a barrier metal film 38 is formed, and the second interconnect layer 41 is formed thereon by burying copper (Cu) in the trench. The barrier metal film 38 is formed by depositing a tantalum (Ta) film to a thickness of 30 nm.

The second-contact interlayer insulating film 43 is formed by sequentially depositing a silicon nitride (SiN) film 44, a Low-k film 45 (silicon oxycarbide (SiOC) film), and a silicon dioxide (SiO₂) film 46. In the second-contact interlayer insulating film 43, a second contact hole 47 that is connected to the second interconnect layer 41 is formed. Inside the second contact hole 47, the second contact layer 51 is formed by filling the hole 47 with copper (Cu) with the intermediary of a barrier metal film 48 therebetween.

The pad 61 is formed by depositing a titanium (Ti) film 62 to a thickness of 50 nm, and then depositing thereon an aluminum (Al) film 63 to a thickness of 500 nm.

Over the second-contact interlayer insulating film 43, a passivation film 81 covering the pad 61 is formed. A pad opening 82 is formed in the passivation film 81 over the pad 61. The passivation film 81 is formed by depositing a silicon nitride (SiN) film to a thickness of 500 nm.

In the semiconductor device 1, the protective member 71 formed of the protective layers 101 to 104 is formed under the pad 61. Therefore, even when a crack is generated in the pad 61 due to contact of a probe needle thereto, intruding water and so on are blocked by the protective layers 101 to 104 formed under the pad 61. Thus, the water hardly penetrates into the external of the region surrounded by the protective member 71, which makes it possible to maintain the performance characteristics of the circuit-part interlayer insulating films formed outside the pad 61 and the protective member 71 (the second-contact interlayer insulating film 43, the second-interconnect interlayer insulating film 33, the first-contact interlayer insulating film 23, and the first-interconnect interlayer insulating film 13). Thus, an advantage is achieved that characteristic deterioration and reliability deterioration, such as increases of the capacitance between interconnects and the amount of leakage current between interconnects in the circuit part, can be suppressed without involving an area increase.

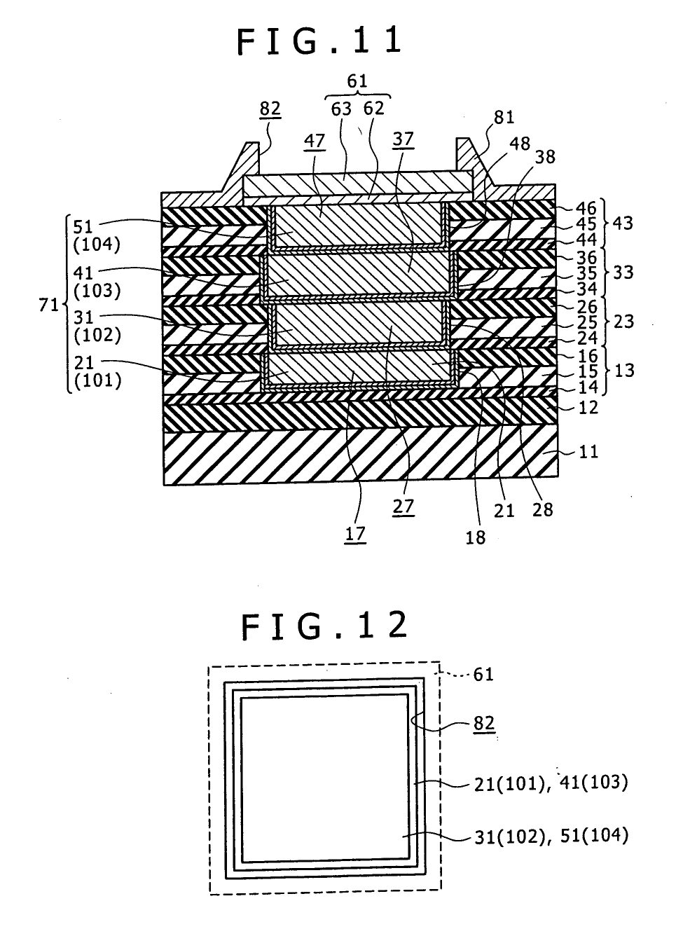

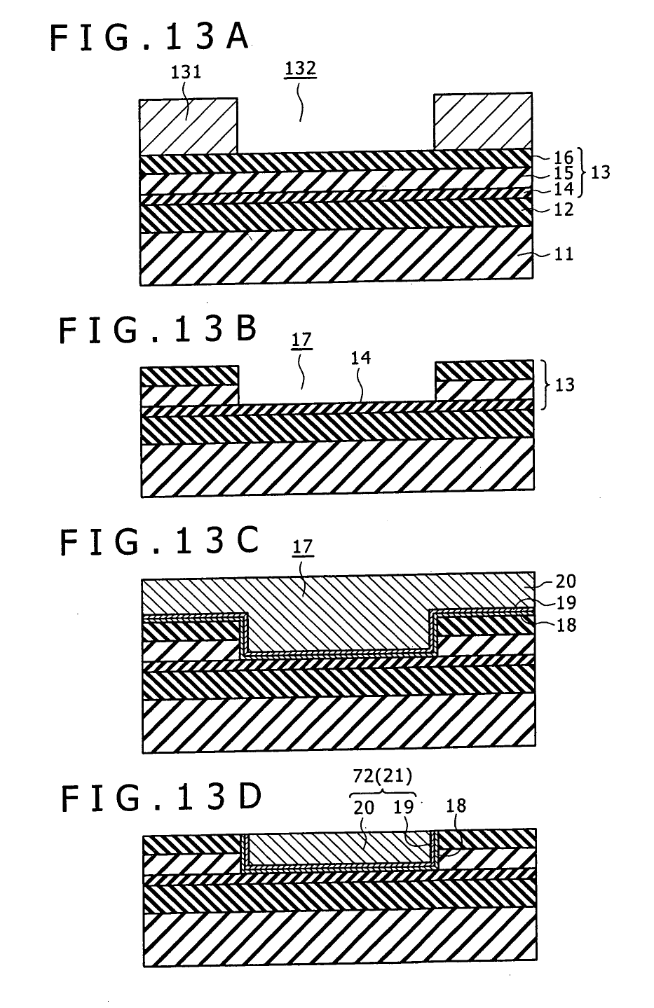

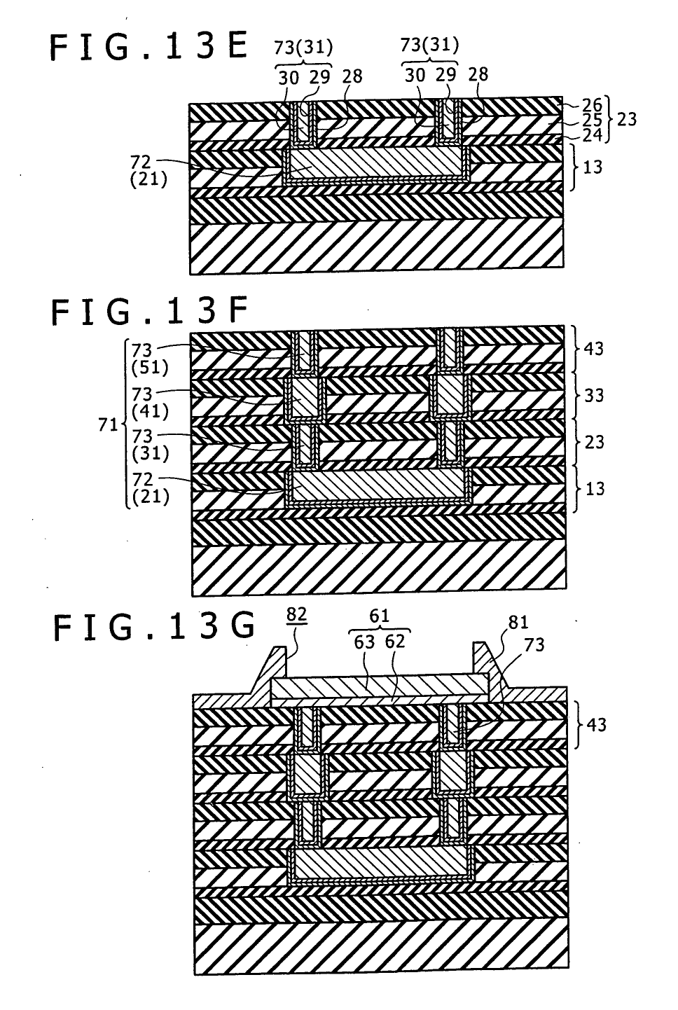

One example of a manufacturing process for a semiconductor device of an embodiment of the invention will be described below with reference to the manufacturing step diagrams of FIGS. 13A to 13G. FIGS. 13A to 13G are diagrams for explaining an example of a manufacturing method for the semiconductor device of the first embodiment.

Referring initially to FIG. 13A, the insulating film 12 is formed on the semiconductor substrate 11. A silicon substrate is used as the semiconductor substrate 11. The insulating film 12 is formed by depositing a silicon dioxide (SiO₂) film to a thickness of 500 nm. Subsequently, the first-interconnect interlayer insulating film 13 is formed. The first-interconnect interlayer insulating film 13 is formed by sequentially deposing the silicon nitride (SiN) film 14 with a thickness of 50 nm, the Low-k film 15 (silicon oxycarbide (SiOC) film) of 150 nm, and the silicon dioxide (SiO₂) film 16 of 150 nm. Each film included in the first-interconnect interlayer insulating film 13 can be deposited by chemical vapor deposition (CVD).

Subsequently, a resist film 131 is formed on the first-interconnect interlayer insulating film 13, and then the resist film 131 is processed by photolithography to thereby form a first-interconnect trench pattern 132. At this time, as shown in the drawing, a part of the first-interconnect trench pattern 132 is formed into a bottom-portion trench pattern shape for forming a bottom portion of a protective member that is formed under a pad and has moisture resistance. Thus, the formation of the bottom portion by use of the first interconnect layer is allowed.

Referring next to FIG. 13B, the first interconnect trench 17 is formed in the first-interconnect interlayer insulating film 13 with use of the resist film 131 (see FIG. 13A) as the etching mask. At this time, as shown in the drawing, a part of the first interconnect trench 17 is formed as a bottom portion trench for forming the bottom portion of the protective member that is formed under the pad and has moisture resistance. This processing is carried out by plasma etching. In this etching, the silicon nitride film 14 serves as an etch stopper. After the etching, the resist film 131 is removed. Note that FIG. 13B illustrates the state after the removal of the resist film 131.

Subsequently, as shown in FIG. 13C, the barrier metal film 18 and a seed layer 19 are formed on the first-interconnect interlayer insulating film 13 including the inner surface of the first interconnect trench 17. The barrier metal film 18 is formed by depositing a tantalum (Ta) film to a thickness of 30 nm by sputtering. The seed layer 19 is formed by depositing a copper (Cu) film to a thickness of 50 nm by sputtering. Subsequently, a copper (Cu) film 20 is deposited to a thickness of 1 μm so that the inside of the first interconnect trench 17 is filled with the copper (Cu) film 20. Plating can be used for the deposition of the copper (Cu) film 20. After the deposition, the excess copper film 20 (including the seed layer 19) and barrier metal film 18 over the first-interconnect interlayer insulating film 13 are removed. This removal is carried out by CMP.

As a result, as shown in FIG. 13D, the first interconnect layer 21 formed of the copper film 20 (including the seed layer 19) is formed inside the first interconnect trench 17 with the intermediary of the barrier metal film 18 therebetween. This first interconnect layer 21 forms the bottom portion 72 included in the protective member with moisture resistance.

Referring next to FIG. 13E, the first-contact interlayer insulating film 23 and the first contact layer 31 are formed by a method similar to the forming method for the first-interconnect interlayer insulating film 13 and the first interconnect layer 21. This first contact layer 31 forms a part of the wall portion 73 that is connected to the bottom portion 72 and is included in the protective member with moisture resistance. This wall portion 73 is formed at the position under the outer circumference of the pad 61 to be formed later, as shown in FIG. 2 for example.

A specific example of the forming method for the first-contact interlayer insulating film 23 and the first contact layer 31 is as follows. Specifically, the first-contact interlayer insulating film 23 is formed on the first-interconnect interlayer insulating film 13 in a manner of covering the first interconnect layer 21. The first-contact interlayer insulating film 23 is formed by sequentially depositing the silicon nitride (SiN) film 24, the Low-k film 25 (silicon oxycarbide (SiOC) film), and the silicon dioxide (SiO₂) film 26. Each film included in the first-contact interlayer insulating film 23 can be deposited by CVD.

Subsequently, a resist film (not shown) is formed on the first-contact interlayer insulating film 23, and then the resist film is processed by photolithography to thereby form a first-contact hole pattern (not shown).

Subsequently, the first contact hole 27 is formed in the first-contact interlayer insulating film 23 with use of the resist film as the etching mask. At this time, as shown in the drawing, a part of the first contact hole 27 is formed as a wall portion trench for forming a wall portion of the protective member that is formed under the pad and has moisture resistance. This processing is carried out by plasma etching. After the etching, the resist film is removed. Note that FIG. 13E illustrates the state after the removal of the resist film.

Subsequently, the barrier metal film 28 and a seed layer 29 are formed on the first-contact interlayer insulating film 23 including the inner surface of the first contact hole 27. The barrier metal film 28 is formed by depositing a tantalum (Ta) film by sputtering. The seed layer 29 is formed by depositing a copper (Cu) film 30 by sputtering. Subsequently, the copper film 30 is deposited so that the inside of the first contact hole 27 is filled with the copper film 30. Plating can be used for the deposition of the copper film 30. After the deposition, the excess copper film 30 (including the seed layer 29) and barrier metal film 28 over the first-contact interlayer insulating film 23 are removed. This removal is carried out by CMP. As a result, the first contact layer 31 connected to the upper part of the first interconnect layer 21 is formed inside the first contact hole 27 with the intermediary of the barrier metal film 28 therebetween.

Subsequently, as shown in FIG. 13F, by processes similar to the forming processes for the first-interconnect interlayer insulating film 13, the first interconnect layer 21, the first-contact interlayer insulating film 23, and the first contact layer 31, the second-interconnect interlayer insulating film 33 is formed on the first-contact interlayer insulating film 23 in which the first contact layer 31 has been formed. The second interconnect layer 41 connected to the first contact layer 31 is formed in the second-interconnect interlayer insulating film 33. In addition, the second-contact interlayer insulating film 43 is formed on the second-interconnect interlayer insulating film 33 to cover the second interconnect layer 41, and the second contact layer 51 connected to the second interconnect layer 41 is formed in the second-contact interlayer insulating film 43. This second interconnect layer 41 and the second contact layer 51 form a part of the wall portion 73 that is connected to the previously formed wall portion 73 and is included in the protective member with moisture resistance. This wall portion 73 is formed at the position under the outer circumference of the pad to be formed later, as shown in FIG. 2.

Referring next to FIG. 13G, the pad 61 for achieving electrical coupling to the external is formed on the second-contact interlayer insulating film 43. The pad 61 is formed by depositing the titanium (Ti) film 62 to a thickness of 50 nm, and then depositing thereon the aluminum (Al) film 63 to a thickness of 500 nm. Sputtering can be used for the deposition of these films 62 and 63. Another deposition method other than sputtering is also available. After the deposition, a resist film (not shown) is formed on the aluminum film 63, followed by the formation of a pad pattern by photolithography. Subsequently, etching is carried out with use of the pad pattern as the etching mask to thereby form the pad 61. The lower face of the outer circumference of the pad 61 is connected to the wall portion 73. Plasma etching is used as the etching for the formation of the pad 61.

After the formation of the pad 61, the passivation film 81 covering the pad 61 is formed over the second-contact interlayer insulating film 43. Subsequently, the pad opening 82 is formed in the passivation film 81 over the pad 61. To form the passivation film 81, a silicon nitride (SiN) film is deposited to a thickness of 500 nm. CVD can be used for the deposition of the SiN film. Subsequently, a typical resist mask is formed, and then the pad opening 82 is formed in the passivation film 81 with use of the resist mask as the etching mask. Plasma etching can be used for this etching.

The above-described manufacturing method has a characteristic feature that the bottom portion 72 of the protective member 71 having moisture resistance can be formed by the first interconnect layer 21, and the wall portion 73 can be formed by the first contact layer 31, the second interconnect layer 41 and the second contact layer 51, by use of an existing process. Therefore, the interlayer insulating films under the pad 61 can be surrounded by the protective member 71 while the load associated with the process is minimized. Consequently, even if the pad 61 suffers from damage such as a crack and water permeates the interlayer insulating films under the pad 61, the protective member 71 prevents the water from entering interlayer insulating films other than those under the pad 61, e.g., the circuit-part interlayer insulating films, and hence the permeation of water is advantageously avoided. Thus, the reliability of the circuit part is enhanced, which can improve the reliability of the semiconductor device.

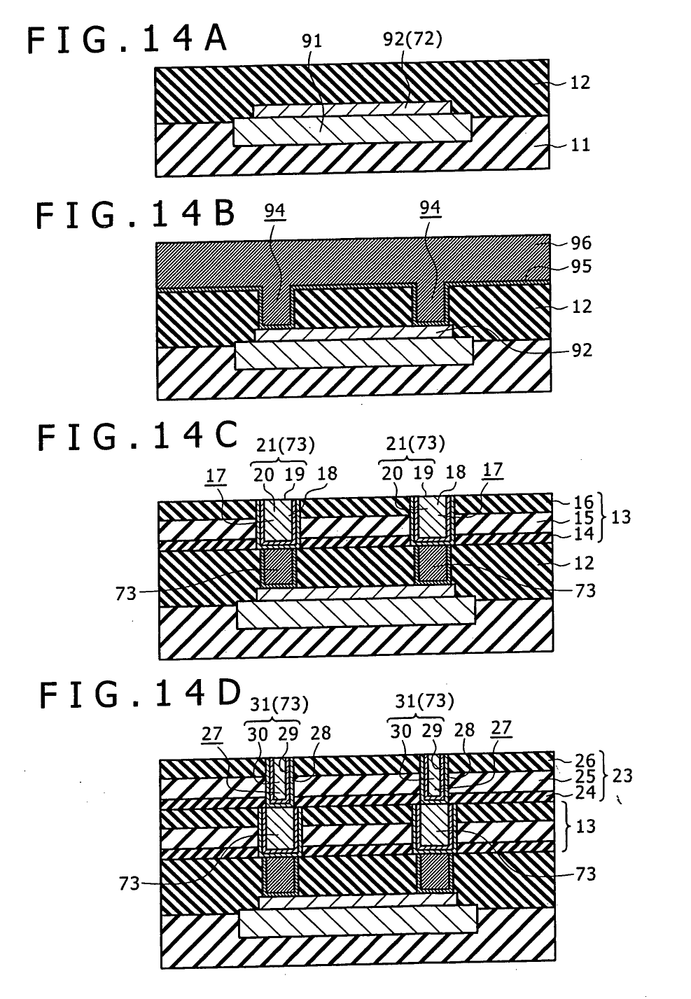

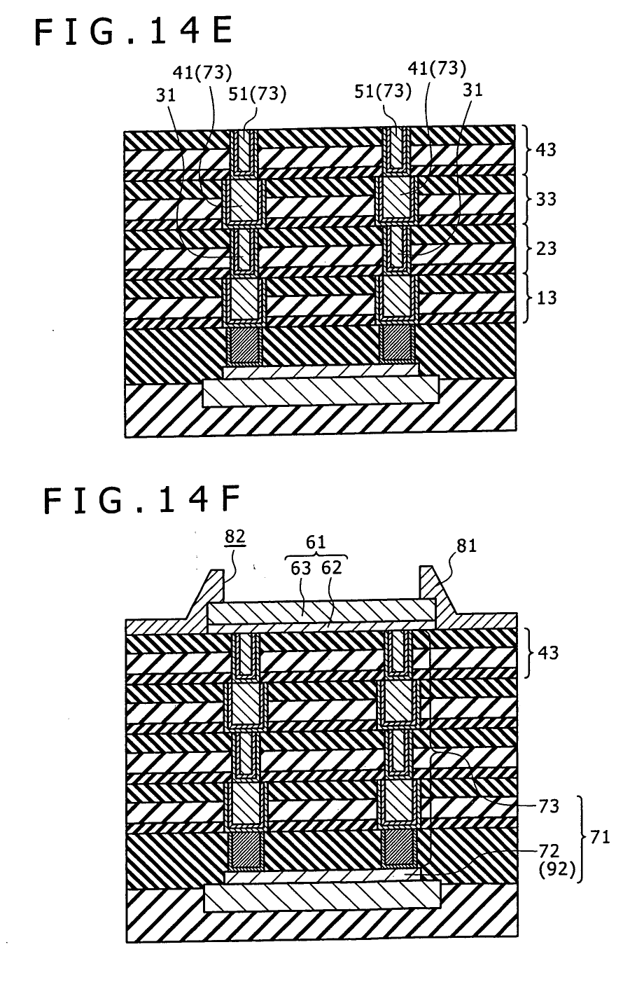

One example of a manufacturing process for another semiconductor device of an embodiment of the invention, will be described below with reference to the manufacturing step diagrams of FIGS. 14A to 14F. FIGS. 14A to 14F are diagrams for explaining an example of a manufacturing method for the semiconductor device of the third embodiment.

Referring initially to FIG. 14A, the element isolation region 91 is formed in the semiconductor substrate 11. A silicon substrate is used as the semiconductor substrate 11. The element isolation region 91 is formed based on a shallow trench isolation (STI) structure. On the semiconductor substrate 11, semiconductor elements such as transistors and capacitors, a gate electrode layer, etc. are formed although not illustrated in the drawings. At this time, a part of the gate electrode layer 92 is formed also on the element isolation region 91 that is located under a pad to be formed later. This gate electrode layer 92 serves as the bottom portion 72 of a protective member. Subsequently, formed on the semiconductor substrate 11 is the insulating film 12 in which a lower contact layer connected to the gate electrode layer 92 is to be formed. The insulating film 12 is formed by depositing a silicon dioxide (SiO₂) film to a thickness of 500 nm. CVD can be used for the deposition of the SiO₂ film.

Referring next to FIG. 14B, a lower contact hole 94 that is connected to the gate electrode layer 92, and to the gate electrode, source/drain regions and so on of a transistor (not shown) is formed in the insulating film 12, through typical resist application, formation of an etching mask by lithography, and etching with use of the etching mask. Thereafter, the resist film used as the mask in the etching for forming the lower contact hole 94 is removed.

Subsequently, a barrier metal film 95 is formed on the insulating film 12 including the inner surface of the lower contact hole 94. The barrier metal film 95 is formed by depositing a titanium (Ti) film to a thickness of 30 nm by sputtering. Furthermore, a tungsten film 96 is deposited to a thickness of 400 nm by CVD so that the inside of the lower contact hole 94 is filled with the tungsten film 96. After the deposition, the excess tungsten film 96 and barrier metal film 95 over the insulating film 12 are removed. This removal is carried out by CMP. As a result, the lower contact layer 93 that is formed of the tungsten film 96 and is connected to the upper part of the gate electrode layer 92 is formed inside the lower contact hole 94 with the intermediary of the barrier metal film 95 therebetween. This gate electrode layer 92 forms the bottom portion 72 included in the protective member with moisture resistance. This bottom portion 72 is located below the pad 61 to be formed later and has a size almost equal to the size of the pad 61, as shown in FIG. 6. Note that FIG. 14B illustrates the state before the CMP is carried out.

Referring next to FIG. 14C, the first-interconnect interlayer insulating film 13 is formed on the insulating film 12. The first-interconnect interlayer insulating film 13 is formed by sequentially deposing the silicon nitride (SiN) film 14 with a thickness of 50 nm, the Low-k film 15 (silicon oxycarbide (SiOC) film) of 150 nm, and the silicon dioxide (SiO₂) film 16 of 150 nm. Each film included in the first-interconnect interlayer insulating film 13 can be deposited by CVD.

Subsequently, a resist film (not shown) is formed on the first-interconnect interlayer insulating film 13, and then the resist film is processed by photolithography to thereby form a first-interconnect trench pattern (not shown). At this time, as shown in the drawing, a part of the first-interconnect trench pattern is formed into a wall-portion trench pattern shape for forming a wall portion of the protective member that is formed under the pad and has moisture resistance. Thus, the formation of the bottom portion by use of the first interconnect layer is allowed.

Subsequently, the first interconnect trench 17 is formed in the first-interconnect interlayer insulating film 13 with use of the resist film as the etching mask. At this time, as shown in the drawing, a part of the first interconnect trench 17 is formed as a wall portion trench for forming a wall portion of the protective member that is formed under the pad and has moisture resistance. This processing is carried out by plasma etching. In this etching, the silicon nitride film 14 serves as an etch stopper. After the etching, the resist film is removed. Note that FIG. 14C illustrates the state after the removal of the resist film.

Subsequently, the barrier metal film 18 and a seed layer 19 are formed on the first-interconnect interlayer insulating film 13 including the inner surface of the first interconnect trench 17. The barrier metal film 18 is formed by depositing a tantalum (Ta) film to a thickness of 30 nm by sputtering. The seed layer 19 is formed by depositing a copper (Cu) film to a thickness of 50 nm by sputtering. Subsequently, a copper (Cu) film 20 is deposited to a thickness of 1 μm so that the inside of the first interconnect trench 17 is filled with the copper (Cu) film 20. Plating can be used for the deposition of the copper (Cu) film 20. After the deposition, the excess copper film 20 (including the seed layer 19) and barrier metal film 18 over the first-interconnect interlayer insulating film 13 are removed. This removal is carried out by CMP.

As a result, the first interconnect layer 21 formed of the copper film 20 (including the seed layer 19) is formed inside the first interconnect trench 17 with the intermediary of the barrier metal film 18 therebetween. This first interconnect layer 21 forms a part of the wall portion 73 included in the protective member with moisture resistance.

Referring next to FIG. 14D, the first-contact interlayer insulating film 23 and the first contact layer 31 are formed by a method similar to the forming method for the first-interconnect interlayer insulating film 13 and the first interconnect layer 21. This first contact layer 31 forms a part of the wall portion 73 that is connected to the previously formed wall portion 73 and is included in the protective member having moisture resistance. This wall portion 73 is formed at the position under the outer circumference of the pad 61 to be formed later, as shown in FIG. 6 for example.

A specific example of the forming method for the first-contact interlayer insulating film 23 and the first contact layer 31 is as follows. Specifically, the first-contact interlayer insulating film 23 is formed on the first-interconnect interlayer insulating film 13 in a manner of covering the first interconnect layer 21. The first-contact interlayer insulating film 23 is formed by sequentially depositing the silicon nitride (SiN) film 24, the Low-k film 25 (silicon oxycarbide (SiOC) film), and the silicon dioxide (SiO₂) film 26. Each film included in the first-contact interlayer insulating film 23 can be deposited by CVD.

Subsequently, a resist film (not shown) is formed on the first-contact interlayer insulating film 23, and then the resist film is processed by photolithography to thereby form a first-contact hole pattern (not shown).

Subsequently, the first contact hole 27 is formed in the first-contact interlayer insulating film 23 with use of the resist film as the etching mask. At this time, as shown in the drawing, a part of the first contact hole 27 is formed as a wall portion trench for forming a wall portion of the protective member that is formed under the pad and has moisture resistance. This processing is carried out by plasma etching. After the etching, the resist film is removed. Note that FIG. 14D illustrates the state after the removal of the resist film.

Subsequently, the barrier metal film 28 and a seed layer 29 are formed on the first-contact interlayer insulating film 23 including the inner surface of the first contact hole 27. The barrier metal film 28 is formed by depositing a tantalum (Ta) film by sputtering. The seed layer 29 is formed by depositing a copper (Cu) film by sputtering. Subsequently, a copper (Cu) film 30 is deposited so that the inside of the first contact hole 27 is filled with the copper (Cu) film 30. Plating can be used for the deposition of the copper (Cu) film 30. After the deposition, the excess copper film 30 (including the seed layer 29) and barrier metal film 28 over the first-contact interlayer insulating film 23 are removed. This removal is carried out by CMP. As a result, the first contact layer 31 connected to the upper part of the first interconnect layer 21 is formed inside the first contact hole 27 with the intermediary of the barrier metal film 28 therebetween.

Subsequently, as shown in FIG. 14E, by processes similar to the forming processes for the first-interconnect interlayer insulating film 13, the first interconnect layer 21, the first-contact interlayer insulating film 23, and the first contact layer 31, the second-interconnect interlayer insulating film 33 is formed on the first-contact interlayer insulating film 23 in which the first contact layer 31 has been formed. The second interconnect layer 41 connected to the first contact layer 31 is formed in the second-interconnect interlayer insulating film 33. In addition, the second-contact interlayer insulating film 43 is formed on the second-interconnect interlayer insulating film 33 to cover the second interconnect layer 41, and the second contact layer 51 connected to the second interconnect layer 41 is formed in the second-contact interlayer insulating film 43. The second interconnect layer 41 and the second contact layer 51 form a part of the wall portion 73 that is connected to the previously formed wall portion 73 and is included in the protective member having moisture resistance. This wall portion 73 is formed at the position under the outer circumference of the pad to be formed later, as shown in FIG. 6. In this manner, the wall portion 73 is formed through sequential deposition of each layer.

Referring next to FIG. 14F, the pad 61 for achieving electrical coupling to the external is formed on the second-contact interlayer insulating film 43. The pad 61 is formed by depositing the titanium (Ti) film 62 to a thickness of 50 nm, and then depositing thereon the aluminum (Al) film 63 to a thickness of 500 nm. Sputtering can be used for the deposition of these films 62 and 63. Another deposition method other than sputtering is also available. After the deposition, a resist film (not shown) is formed on the aluminum film 63, followed by the formation of a pad pattern by photolithography. Subsequently, etching is carried out with use of the pad pattern as the etching mask to thereby form the pad 61. The lower face of the outer circumference of the pad 61 is connected to the wall portion 73. Plasma etching is used as the etching for the formation of the pad 61.

After the formation of the pad 61, the passivation film 81 covering the pad 61 is formed over the second-contact interlayer insulating film 43. Subsequently, the pad opening 82 is formed in the passivation film 81 over the pad 61. To form the passivation film 81, a silicon nitride (SiN) film is deposited to a thickness of 500 nm. CVD can be used for the deposition of the SiN film. Subsequently, a typical resist mask is formed, and then the pad opening 82 is formed in the passivation film 81 with use of the resist mask as the etching mask. Plasma etching can be used for this etching.

The above-described manufacturing method has a characteristic feature that the bottom portion 72 of the protective member 71 having moisture resistance can be formed by the gate electrode layer 92, and the wall portion 73 can be formed by the lower contact layer 93, the first interconnect layer 21, the first contact layer 31, the second interconnect layer 41 and the second contact layer 51, by use of an existing process. Therefore, the interlayer insulating films under the pad 61 can be surrounded by the protective member 71 while the load associated with the process is minimized. Consequently, even if the pad 61 suffers from damage such as a crack and water permeates the interlayer insulating films under the pad 61, the protective member 71 prevents the water from entering interlayer insulating films other than those under the pad 61, e.g., the circuit-part interlayer insulating films, and hence the permeation of water is advantageously avoided. Thus, the reliability of the circuit part is enhanced, which can improve the reliability of the semiconductor device.

If the formation of a partition wall is intended like the second, fourth and fifth embodiments, the partition wall can be formed similarly to the wall portion 73 by a process for forming the wall portion 73 that is in the same layer as the layer in which the partition wall is to be formed. That is, the partition wall can be formed by changing the pattern of a mask from the pattern for forming the wall portion 73 to that for forming the partition wall. Furthermore, if the formation of an intermediate protective layer is intended like the second and fourth embodiments, etc., the intermediate protective layer can be formed instead of the wall portion 73 by a process for forming the wall portion 73 in the same layer as the layer in which the partition wall is to be formed. That is, the intermediate protective layer can be formed by changing the pattern of a mask from the pattern for forming the wall portion 73 to that for forming the intermediate protective layer.

The forming methods for interlayer insulating films, the kinds of interconnect materials, and the kinds of materials for interlayer insulating films in the above-described embodiments are an example. Other materials used in typical semiconductor devices can also be used.

As the forming method for interconnects, a dual damascene method in which a contact layer and an interconnect layer are continuously formed may be used instead of a typical damascene method. If aluminum (Al) or tungsten (W) is used as the metal material of the respective interconnects, a pattern forming technique based on the formation of an etching mask by typical photolithography and plasma etching employing the etching mask can also be used.

As the forming method for interlayer insulating films, besides CVD, a method based on a combination of spin-coating application and baking or a combination of printing and baking can also be employed.

Although copper is used in the embodiments as an example of the metal material of major part of interconnects, another metal material such as an alloy of copper and another metal, aluminum (Al), tungsten (W), silver (Ag), gold (Au), or platinum (Pt) can also be used. Tantalum is used in the embodiments as an example of the material of barrier metal films. Instead of this, titanium (Ti), molybdenum (Mo), tungsten (W), a nitride film of Ti, Mo, W or Ta, an oxide film of Ti, Mo, W or Ta, or a multilayer film of these nitride and oxide films may be used.

As the films included in interlayer insulating films in the embodiments, a silicon nitride (SiN) film at the lowest level, a silicon oxycarbide (SiOC) film as a low dielectric constant film thereon, and a silicon dioxide (SiO₂) film thereon are used as an example. The SiN film, SiOC film and SiO₂ film serve as a film for preventing the diffusion of copper, a film for achieving a low dielectric constant, and a film to be polished, respectively. Instead of the silicon nitride (SiN) film, a silicon carbide (SiC) film or a silicon carbonitride (SiNC) film can be used. Instead of the silicon oxycarbide (SiOC) film, a methylsilsesquioxane (MSQ) film, a hydrogen silsesquioxane (HSQ) film, a porous film, a silicon oxyfluoride (SiOF) film, or a Low-k organic film such as a polyarylether film or a polyarylether fluoride film can be used. Instead of the silicon dioxide (SiO₂) film, a silicon oxyfluoride (SiOF) film can be used.

In the above-described embodiments, a two-level interconnect structure is employed as an example of multilevel interconnect structures. However, three- or more-level interconnect structure is also available, and the number of layers of a protective member having moisture resistance may be any number. In the embodiments, the wall portion 73 of the protective member 71 is formed in such a manner that the wall portion 73 borders the position under the outer circumference of the pad 61. However, another structure is also available in which the wall portion 73 surrounds the position under the outer circumference of the pad 61 double, triple or more times. Furthermore, the wall portion 73 may have a loop shape or a helical shape as long as it has a closed shape.

In the embodiments, a lattice shape, a honeycomb shape, and a truss shape are cited as examples of the shape of the partition walls 75, 76 and 78 that are formed of the respective contact layers. However, the shape thereof is not limited thereto but may be any shape. In addition, the partition walls 75, 76 and 78 with a shape similar to any of a lattice shape, a honeycomb shape, etc., may be formed at the same levels as those of the contact layers as well as at the same levels as those of the respective intermediate interconnect layers.

The silicon substrate used for the semiconductor substrate 11 in the embodiments may be either of a P-type silicon substrate or an N-type silicon substrate. Alternatively, a silicon-on-insulator (SOI) substrate may be used.

Although photolithography is employed as the patterning method in the embodiments, electron beam lithography and X-ray lithography are also available. Furthermore, although plasma etching is employed as the etching in the embodiments, wet etching with a chemical or a combination of plasma etching and wet etching with a chemical may be employed.

In the embodiments, as the bottom portion 72 of the protective member 71, an interconnect layer that is formed into a plate shape at the lowest level is used. Instead of this, a contact layer that is formed into a plate shape at the lowest level may be used. In addition, a gate electrode layer is used as the bottom portion 72 of the protective member 71 in some of the embodiments. Instead of this, a diffusion layer may be used therefor.

Moreover, in the embodiments, the wall portion 73 of the protective member 71 is formed of a metal layer or a metal compound layer since it is formed of an interconnect layer or a contact layer. However, it may be formed of e.g. an insulating film as long as it has moisture resistance. For example, a silicon nitride film is available.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device that includes a pad over a multilevel interconnect formed by stacking an interconnect layer and an interlayer insulating film, the semiconductor device comprising:
a protective member that is formed in a continuous manner under outer circumference of the pad and has moisture resistance, the protective member surrounding the interlayer insulating film under the pad.

2. The semiconductor device according to claim 1, wherein
the protective member has a multilayer structure.

3. The semiconductor device according to claim 1, wherein
the protective member has a multilayer structure formed of the interconnect layer and the contact layer that are used for the multilevel interconnect, and
the protective member includes a wall portion and a bottom portion, the wall portion being formed of the interconnect layer or the contact layer that is continuously connected to the pad, the bottom portion being formed of the contact layer or the interconnect layer that is in a lowest layer of layers in which the protective member is formed.

4. The semiconductor device according to claim 1, further comprising:
a partition wall that has moisture resistance and is provided in the interlayer insulating film surrounded by the pad and the protective member.

5. The semiconductor device according to claim 1, further comprising:
an intermediate protective layer that is provided between the pad and a bottom portion of the protective member and is continuously connected to a wall portion of the protective member.

6. The semiconductor device according to claim 1, wherein
a bottom portion of the protective member is connected to an interconnect layer that is at a lower level than the bottom portion.

7. The semiconductor device according to claim 1, wherein
the protective member has a multilayer structure formed of the interconnect layer and the contact layer that are used for the multilevel interconnect, and
a bottom portion of the protective member is formed of a diffusion layer or a gate electrode layer.

8. The semiconductor device according to claim 7, further comprising:
a partition wall that has moisture resistance and is provided in the interlayer insulating film surrounded by the pad and the protective member.

9. The semiconductor device according to claim 7, further comprising:
an intermediate protective layer that is provided between the pad and a bottom portion of the protective member and is continuously connected to a wall portion of the protective member.

10. A semiconductor device that includes a pad over a multilevel interconnect formed by stacking an interconnect layer and an interlayer insulating film, the semiconductor device comprising:
a protective layer that is connected to a lower face of the pad and has moisture resistance.

11. The semiconductor device according to claim 10, wherein
the protective layer has a multilayer structure formed of the interconnect layer and the contact layer that are used for the multilevel interconnect, and
the protective layer is formed of a plurality of k layers.
